(19) United States
(12) Patent Application Publication
(10) Pub. No.: US 2026/0351509 A1
(43) Pub. Date: Nov. 5, 2026

(54) DIRECT WRITING SYSTEM USED FOR ELECTRON BEAM LITHOGRAPHY

(71) Applicant: Taiwan Semiconductor Manufacturing Company, Ltd., Hsinchu (TW)

(72) Inventors: Cheng-Hsien Chou, Tainan (TW); Yung-Lung Lin, Taichung (TW); Chun Liang Chen, Tainan (TW); Kuan-Liang Liu, Pingtung County (TW); Chin-Yu Ku, Hsinchu (TW); Jong-Yuh Chang, Hsinchu (TW)

(21) Appl. No.: 19/740,314

(22) Filed: Jul. 14, 2026

Related U.S. Application Data
(62) Division of application No. 18/464,243, filed on Sep. 10, 2023.
(60) Provisional application No. 63/383,505, filed on Nov. 13, 2022.

(51) Int. Cl. H01J 37/147; H01J 37/317

(52) U.S. Cl. CPC H01J 37/1472; H01J 37/3174

(57) ABSTRACT

A method for fabricating a deflecting plate used in electron beam lithography (EBL) involves utilizing a silicon-on-insulator (SOI) substrate. The SOI substrate includes an insulator layer positioned between a top device layer and a bottom handle substrate. The fabrication process includes forming multiple deflecting apertures that extend vertically completely through the device layer. The bottom opening of each aperture is formed to be exactly coplanar with the top surface of the insulator layer. A cavity is formed within the handle substrate, extending to a cavity bottom wall that is also coplanar with the top surface of the insulator layer. This method ensures that the bottom opening of every deflecting aperture is directly exposed to, and spatially connected with, the underlying cavity.

### CROSS-REFERENCE TO RELATED APPLICATIONS

The present application is a division of U.S. Non-Provisional Patent Application No. 18/464,243 filed Sep. 10, 2023, which claims priority to U.S. Provisional Patent Application 63/383,505 filed Nov. 13, 2022, the entire disclosure of which is incorporated herein by reference.

### FIELD

Embodiments of the present disclosure relate generally to electron beam lithography (EBL), and more particularly to an improved direct writing system.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area.

While some integrated device manufacturers (IDMs) design and manufacture integrated circuits (IC) themselves, fabless semiconductor companies outsource semiconductor fabrication to semiconductor fabrication plants or foundries. Semiconductor fabrication consists of a series of processes in which a device structure is manufactured by applying a series of layers onto a substrate. This involves the deposition and removal of various thin film layers. The areas of the thin film that are to be deposited or removed are controlled through photolithography. Each of the deposition and removal processes is generally followed by cleaning as well as inspection steps. Therefore, both IDMs and foundries rely on numerous semiconductor equipment and semiconductor fabrication materials, often provided by vendors. There is always a need for customizing or improving those semiconductor equipment and semiconductor fabrication materials, which results in more flexibility, reliability, and cost-effectiveness.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a diagram illustrating an example electron beam lithography (EBL) system in accordance with some embodiments.

FIG. 1B is a schematic diagram illustrating a cross-sectional view of the direct writing system shown in FIG. 1A in accordance with some embodiments.

FIG. 2 is a flowchart diagram illustrating an example method for fabricating a direct writing system in accordance with some embodiments.

FIGS. 3A-3D are cross-sectional diagrams illustrating the direct writing system at various fabrication stages in accordance with some embodiments.

FIG. 4 is a flowchart diagram illustrating an example method for fabricating a silicon-on-insulator (SOI) substrate in accordance with some embodiments.

FIGS. 5A-5D are cross-sectional diagrams illustrating the SOI substrate at various fabrication stages in accordance with some embodiments.

### DETAILED DESCRIPTION OF THE INVENTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In addition, source/drain region(s) may refer to a source or a drain, individually or collectively dependent upon the context. For example, a device may include a first source/drain region and a second source/drain region, among other components. The first source/drain region may be a source region, whereas the second source/drain region may be a drain region, or vice versa. One of ordinary skill in the art would recognize many variations, modifications, and alternatives.

Some embodiments of the disclosure are described. Additional operations can be provided before, during, and/or after the stages described in these embodiments. Some of the stages that are described can be replaced or eliminated for different embodiments. Some of the features described below can be replaced or eliminated and additional features can be added for different embodiments. Although some embodiments are discussed with operations performed in a particular order, these operations may be performed in another logical order.

### Overview

Electron beam lithography (EBL) is the practice of scanning a focused beam of electrons to draw custom shapes on a surface covered with an electron-sensitive film (sometimes also referred to as a "resist") during an exposing process. The electron beam changes the solubility of the resist, enabling selective removal of either the exposed or non-exposed regions of the resist by immersing it in a solvent during a developing process. The purpose is to create microscopic structures in the resist that can subsequently be transferred to the substrate material, often by etching.

The primary advantage of electron beam lithography is that it can draw custom patterns (sometimes also referred to as the "direct-write" feature or the “direct writing” feature) with sub-10 nm resolution. Additionally, as the electron beam has wavelengths that can be tuned to be very short, EBL can achieve very high resolution. This form of maskless lithography has high resolution but generally low throughput. The corresponding fabrication cost is higher, and the cycle time is longer as compared to photolithography techniques. As a result, multi-electron-beam lithography is introduced, and it can reduce the cycle time significantly since multiple electron beams work independently and in parallel.

A direct writing system is an important component of an EBL system. The direct writing system usually includes a deflecting plate that has an array of deflecting apertures and multiple electrodes that allow for the generation and deflection of multiple electron beams. The deflecting plate has a relatively small size and a complex structure. In particular, the uniformity of the array of deflecting apertures is critical to the precise control of electron beam deflection in the EBL process. However, the formation of deflecting plate in good uniformity is very challenging in the fabrication process of the deflecting plate.

Conventionally, the deflecting plate is fabricated using a bulk silicon substrate. In the conventional methods, the back side of the device layer is thinned down until a predetermined distance to the bottom open ends of the deflecting apertures is achieved. The thinning process may result in the formation of wafer cracks. A handle substrate is then bonded to the back side of the device layer. The bonding process may result in bonding failure. Additionally, due to the predetermined distance to the bottom open ends of the deflecting apertures, the device layer has to be etched through the predetermined distance in the vertical direction, resulting in poor uniformity in the vertical length of the deflecting apertures because of the isotropic nature of the etching process employed.

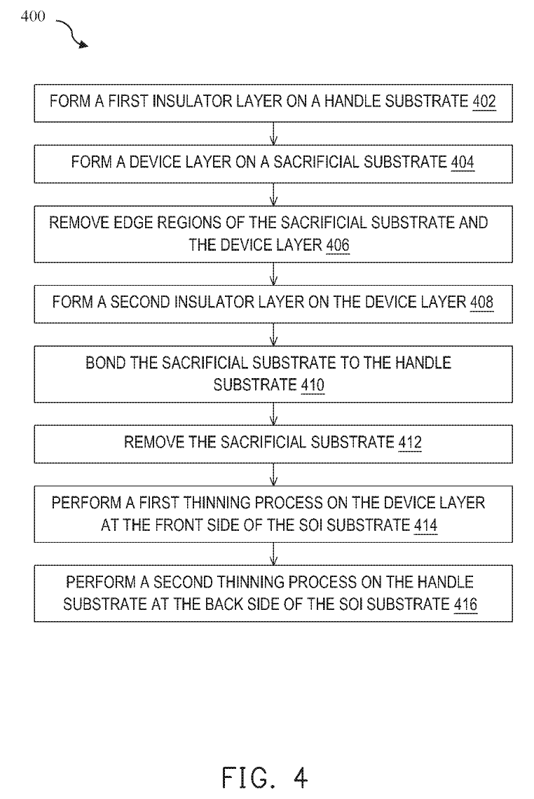

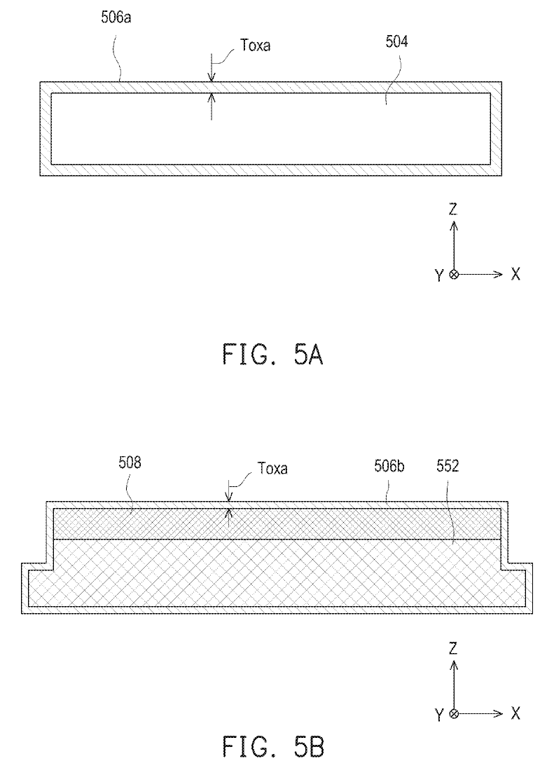

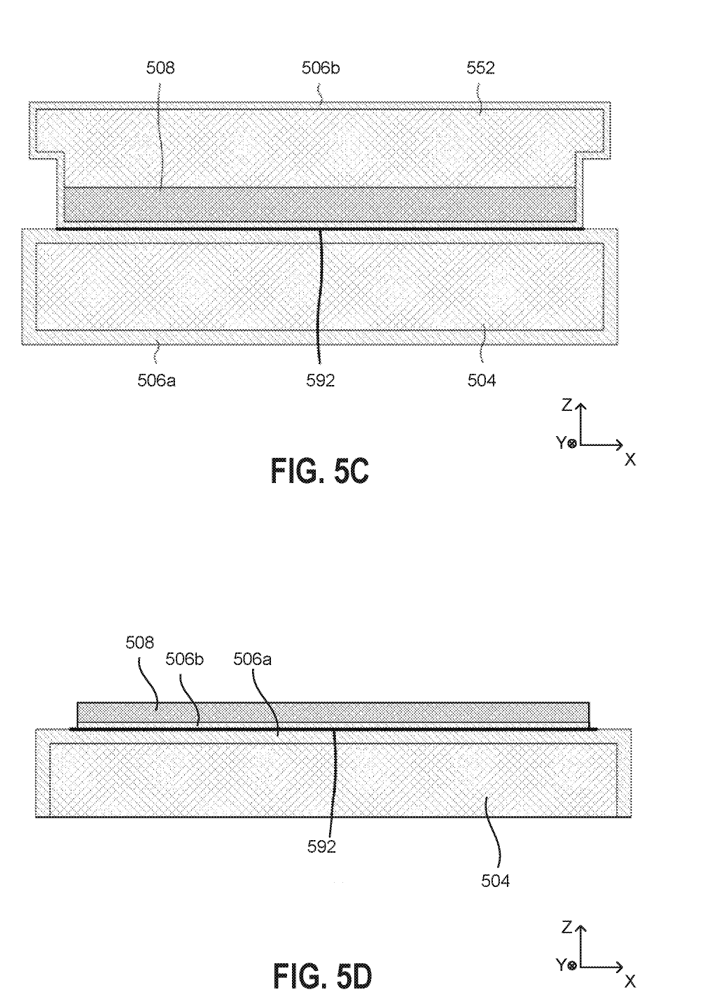

In accordance with some aspects of the disclosure, a novel method for fabricating the deflecting plate is provided. The novel method employs a silicon-on-insulator (SOI) substrate as the substrate for fabricating the deflecting plate. In one implementation, the SOI substrate is fabricated using a double side grinding process, which will be described in detail below with reference to FIGS. 4-5D. The thickness of the device layer and the thickness of the insulator layer is relatively large. A plurality of deflecting apertures is formed in the device layer. Each of the plurality of apertures extends from a top open end to a bottom open end vertically through the device layer. The bottom open end of each aperture is coplanar with the top surface of the insulator layer.

The SOI substrate is pre-fabricated. Therefore, wafer cracks can be avoided because no thinning process is needed to be applied to the back side of the device layer after the deflecting apertures are fabricated. Additionally, bonding failure can be avoided because the handle substrate has been bonded to the device layer through the insulator layer. Lastly, since the bottom open ends are substantially coplanar with the top surface of the insulator layer, there is no device layer that has to be etched through. Thus, the uniformity in the vertical length of the deflecting apertures is significantly improved. From another perspective, the insulator layer functions as a benchmark to guide the formation of both the deflecting apertures in the device layer and the cavity in the handle substrate during the respective etching processes.

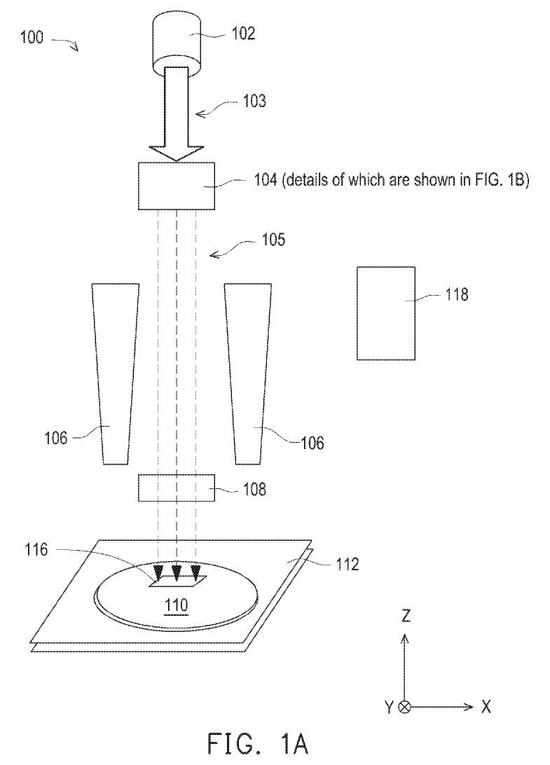

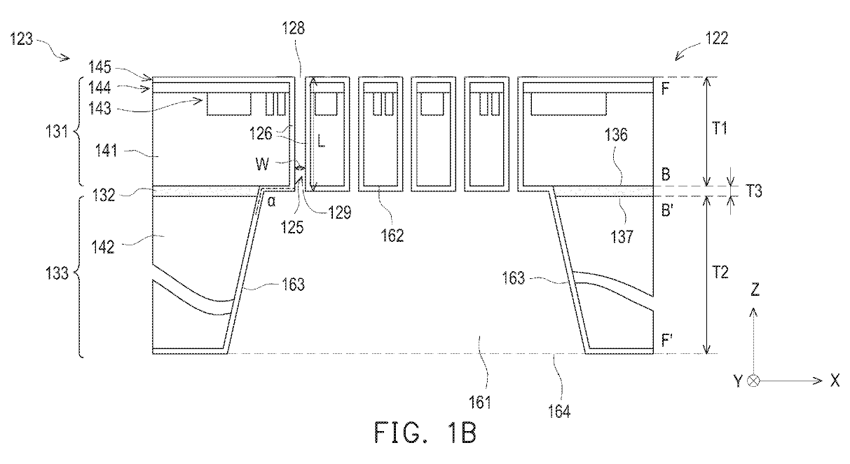

Details of various aspects of the disclosure will be described below in detail with reference to FIGS. 1-5D.

### Example EBL System and Example Direct Writing System

FIG. 1A is a diagram illustrating an example EBL system 100 in accordance with some embodiments. The EBL system 100 is operable to transfer an IC design pattern to an electron beam sensitive resist (sometimes also referred to as a "resist") layer coated on a substrate 110. The EBL system 100 provides a higher resolution than that of conventional optical lithography because an electron beam can be energized to have a shorter wavelength. As will be described below, the EBL system 100 may write an IC pattern directly to a resist layer coated on the substrate 110.

In the example shown in FIG. 1A, the EBL system 100 includes, among other components, an electron source 102, a direct writing system 104, one or more lenses 106, a stopper plate 108, a substrate stage 112, and a control system 118. It should be understood that although the EBL system 100 shown in FIG. 1A is illustrated to include these components, it may include other components in other embodiments as needed. For example, the EBL system 100 may further include an alignment and overlay monitoring system to check and monitor alignment and overlay during the EBL process.

The electron source 102 is operable to provide a broad electron beam 103. It should be understood that other particle sources may be employed in other embodiments. In one implementation, the electron source is an electron gun (sometimes also referred to as an "eGun") with a mechanism to generate electrons, such as by thermal electron emission. In a non-limiting example, the electron gun includes a tungsten (or other suitable material) filament designed and biased to thermally emit electrons. As a result, the broad electron beam 103 is directed to the direct writing system 104, for example, in a vertical direction (i.e., the Z-direction shown in FIG. 1A).

As will be described in detail below with reference to FIGS. 1B and 1C, the direct writing system 104 is operable to generate multiple electron beams 105 from the broad electron beam 103 and deflect the trajectories of the multiple electron beams 105 to directly "write" on the resist as designed. Although the multiple electron beams 105 are schematically shown in FIG. 1A, it should be understood that the trajectories of the multiple electron beams 105 can be fine-tuned and deflected as desired.

The one or more lenses 106 are operable to impact the multiple electron beams 105 passing through the direct writing system 104 for imaging effects during the EBL process. In one embodiment, the lenses 106 include a condenser lens to focus the multiple electron beams 105 into a smaller diameter. In other embodiments, the lenses 106 may further include an objective lens properly configured. Various lenses, such as magnets, are designed to provide forces to the electrons in the multiple electron beams 105 for proper imaging effects, such as focusing.

The stopper plate 108 is operable to switch one or more of the multiple electron beams 105 on or off. In one example, the stopper plate 108 is capable of switching the multiple electron beams on or off individually.

As shown in FIG. 1A, the substrate 110 to be exposed is a wafer, such as a silicon wafer, for the fabrication of integrated circuits. The substrate 110 is positioned on the substrate stage 112.

The substrate 110 is coated with a resist layer to be patterned in an EBL process using the EBL system 100. The resist layer includes a resist material sensitive to electrons. When the resist material is exposed to the electrons, the solubility of the resist material changes, enabling selective removal of either the exposed or non-exposed regions of the resist layer during the developing process. In some implementations, the resist layer is a positive resist layer. Electrons break polymer backbone bonds and transfer the exposed polymer into fragments of lower molecular weight. A solvent developer selectively washes away the lower molecular weight fragments and leaves the unexposed portion of the resist layer intact. In other implementations, the resist layer is a negative resist layer. Electrons cross-link the polymer chains together so that they are less soluble in the solvent developer. The exposed portion of the resist layer is, therefore, left intact. In one example, the resist material includes polymethyl methacrylate (PMMA).

In one embodiment, the substrate stage 112 is operable to move such that one or more of the multiple electron beams 105 are directed to various locations of the resist layer on the substrate 110. In some implementations, the multiple electron beams 105 are directed to a certain region 116 of the resist layer coated on the substrate 110. As explained above, the multiple electron beams 105 are controlled to pattern the region 116 in parallel, achieving a reduced cycle time and increased throughput.

The control system 118 is connected to various components of the EBL system 100 (e.g., the electron source 102, the direct writing system 104, the one or more lenses 106, the stopper plate 108, and the substrate stage 112). The control system 118 is operable to control various components of the EBL system 100. In one embodiment, the control system 118 includes one or more processors, a memory device, a storage device, a bus, a communication unit, an input/output (I/O) unit, and the like. In one embodiment, the control system 118 is operable to read an electronic file including the desired patterns to be transferred to the substrate 110 and control various components of the EBL system 100 based on the electronic file to pattern the substrate 110 accordingly.

In one embodiment, the EBL system 100 further includes a pattern processing module operable to extract various patterns from IC design layouts and, optionally, perform various corrections to the IC design layouts. In another embodiment, the pattern processing module is integrated into the control system 118. In yet another embodiment, the pattern processing module is remotely connected to the EBL system 100.

FIG. 1B is a schematic diagram illustrating a cross-sectional view of the direct writing system 104 shown in FIG. 1A in accordance with some embodiments. It should be understood that FIG. 1B is not drawn to scale. In the illustrated example of FIG. 1B, the direct writing system 104 shown in FIG. 1A includes, among other things, a deflecting plate 122.

The deflecting plate 122 includes, among other things, a silicon-on-insulator (SOI) substrate 123. The SOI substrate 123 further includes a device layer 141, an insulator layer 132, and a handle substrate 142. The device layer 141 has a front side (denoted as "F") and a bottom side (denoted as "B"). Likewise, the handle substrate 142 also has a front side (denoted as "F'" and a back side (denoted as "B'"). The insulator layer 132 has a top surface (may also be referred to as the “second surface”) 136 and a bottom surface (may also be referred to as the “first surface”)137. As illustrated in FIG. 1B, the back side (B) of the device layer 141 is in contact with or coupled to the insulator layer 132 at the top surface 136, and the back side (B') of the handle substrate 142 is in contact with or coupled to the insulator layer 132 at the bottom surface 137. As will be explained below with reference to FIGS. 4-5D, the insulator layer 132 may include a first insulator layer and a second insulator layer bonded together in some embodiments.

In some embodiments, the deflecting plate 122 may further include at least one additional layer (e.g., the first additional layer 144 and the second additional layer 145) disposed on the front side (F) of the device layer 141. The device layer 141, the first additional layer 144, and the second additional layer 145 disposed on the device layer 141 form a top portion 131 of the deflecting plate 122. The handle substrate 142 may also be viewed as a bottom portion 133 of the deflecting plate 122.

The deflecting plate 122 further includes an array of deflecting apertures 125. Each of the deflecting apertures 125 extends vertically through an entire thickness ("T1" as shown in FIG. 1B) of the top portion 131. In some embodiments, the array of the deflecting apertures 125 has a pattern in the horizontal plane (i.e., the X-Y plane shown in FIG. 1B).

In operation, a portion of the broad electron beam 103 shown in FIG. 1A is allowed to sequentially pass through the deflecting apertures 125 to generate the multiple electron beams 105, which may be fine-tuned and deflected as desired.

In some embodiments, the insulator layer 132 is composed of silicon oxide (SiOx). The ratio of oxygen to silicon in the insulator layer 132 may vary depending on the desired property of the insulator layer 132. In some embodiments, the first additional layer 144 disposed on the device layer 141 is a mask layer. The mask layer may include silicon nitride, silicon oxide, silicon oxynitride (SiON), or a combination thereof. The mask layer may provide a mask pattern for forming the deflecting apertures 125 during the fabrication process of the deflecting plate 122. In some embodiments, the second additional layer 145 disposed on the first additional layer 144 is a protective layer. In alternative embodiments, the second additional layer 145 is a bonding layer configured to bond the device layer 141 and a hard mask disposed on the second additional layer 145 during the fabrication of the deflecting plate 122.

In some embodiments, the device layer 141 of the deflecting plate 122 has a total thickness of about 45 µm to about 55 µm, or from about 44 µm to about 53 µm, from about 49 µm to about 51 µm, or close to about 50 µm. In another embodiment, the device layer 141 of the deflecting plate 122 has a total thickness of about 30 µm to about 50 µm. In yet another embodiment, the device layer 141 of the deflecting plate 122 has a total thickness of about 35 µm to about 65 µm. It is noted that the first additional layer 144 and the second additional layer 145 may have a significantly smaller thickness compared to the device layer 141. Thus, the total thickness (T1) of the top portion 131 may be approximate to the thickness of the device layer 141.

In some embodiments, the bottom portion 133 (or the handle substrate 142) has a total thickness ("T2" as shown in FIG. 1B) of about 700 µm to about 750 µm, from about 710 µm to about 740 µm, from about 720 µm to about 730 µm, or close to about 725 µm. In another embodiment, the bottom portion 133 (or the handle substrate 142) has a total thickness of about 700 µm to about 760 µm.

In some embodiments, the insulator layer 132 has a total thickness ("T3" as shown in FIG. 1B), measured by the vertical distance from the top surface 136 to the bottom surface 137, from about 0.1 µm to about 5 µm, or from about 0.2 µm to about 3 µm, or from about 0.3 µm to about 2 µm, or from about 0.5 µm to about 1 µm. In one embodiment, the total thickness of the deflecting plate 122 (i.e., the total thickness of the top portion 131, the insulator layer 132, and the bottom portion 133, or T1 + T2 + T3) is about 750 µm to about 850 µm, or from about 770 µm to about 800 µm, or close to about 775 µm.

In the illustrated example of FIG. 1B, each deflecting aperture 125 is defined by a top open end 128, a bottom open end 129, and a circumferential side wall 126. The deflecting aperture 125 may have variable shapes, e.g., a cylindrical shape or a cuboidal shape, although other shapes are also possible in alternative embodiments. The deflecting aperture 125 has a relatively high aspect ratio defined by the ratio of the vertical length ("L" as shown in FIG. 1B) of the circumferential side wall 126 and the horizontal width ("W" as shown in FIG. 1B) of the top open end 128 (or the bottom open end 129). In some embodiments, the vertical length (L) is approximate to the thickness T1 of the top portion 131, e.g., from about 45 µm to about 55 µm. In some embodiments, the aspect ratio of each deflecting aperture 125 is from about 1 to about 100, or from about 5 to about 50. In other embodiments, the aspect ratio of each deflecting aperture 125 is larger than 100.

It is noted that the bottom open ends 129 of the deflecting apertures 125 are aligned with each other and are also coplanar or substantially coplanar with the top surface 136 of the insulator layer 132. Therefore, the array of deflecting apertures 125 has a high degree of uniformity in the vertical length (L). In some embodiments, the number of the bottom open ends 129 deviated from the top surface 136 is less than about 10%, less than about 5%, less than about 2%, or less than about 1%, based on the total number of the bottom open ends 129. Such high uniformity of the array of the deflecting apertures 125 could significantly improve the performance of electron beam deflection. In some embodiments, the second additional layer 145 is also disposed on and covers the circumferential side wall 126 of each deflecting aperture 125.

In the illustrated example of FIG. 1B, the electron beam passing through each of the deflecting apertures 125 may deflect, and the direction and degree of electron deflection can be fine-tuned and precisely controlled for each of the deflecting apertures. Any suitable mechanisms, for example, an electric field that deflects electrons, may be used.

In the illustrated example of FIG. 1B, the device layer 141 further includes multiple devices 143 fabricated in the device layer 141. As schematically shown in FIG. 1B, the devices 143 are proximate to the front side (F) of the device layer 141. In some embodiments, the devices 143 are multiple transistors, each of which is electrically connected to components corresponding to one of the deflecting apertures 125. In some embodiments, the transistors are configured to provide a control signal (e.g., a control current) applied to the components corresponding to one of the deflecting apertures 125, and the control signal can precisely control the direction and degree of electron deflection for each deflecting aperture 125.

The deflecting plate 122 includes a cavity 161 disposed in the handle substrate 142. The cavity 161 is defined by a cavity open end 164 (represented by a broken line shown in FIG. 1B), a cavity bottom wall 162, and a circumferential cavity side wall 163. As illustrated, the cavity open end 164 is coplanar with the front side (F') of the handle substrate 142, and the cavity bottom wall 162 is coplanar with the top surface 136 of the insulator layer 132 as well as the bottom open ends 129 of the deflecting apertures 125. The cavity bottom wall 162 is in spatial connection with the deflecting apertures 125. In other words, the bottom open ends 129 of the deflecting apertures 125 are completely exposed to the cavity 161. In some embodiments, the cavity 161 has a "funnel-like" shape. For example, the cavity open end 164 may be relatively larger in dimension than the cavity bottom wall 162. In some embodiments, the circumferential cavity side wall 163 forms an angle (α) with the insulator layer 132. In some embodiments, the angle α is larger than 85 degrees. In one example, the angle α is 90 degrees. In another example, the angle α is 100 degrees. In yet another example, the angle α is 110 degrees. In still another example, the angle α is 120 degrees.

### Example Fabrication Process of the Example Direct Writing System

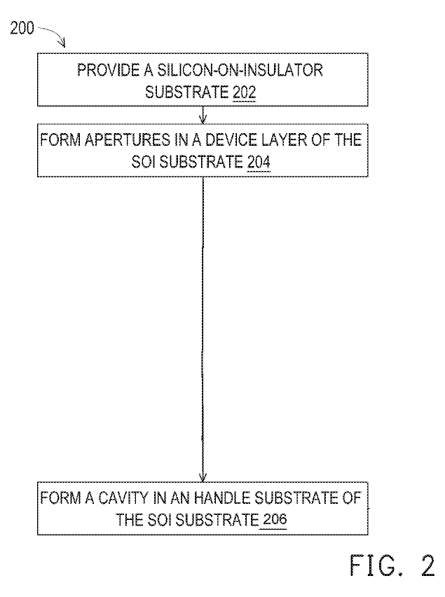

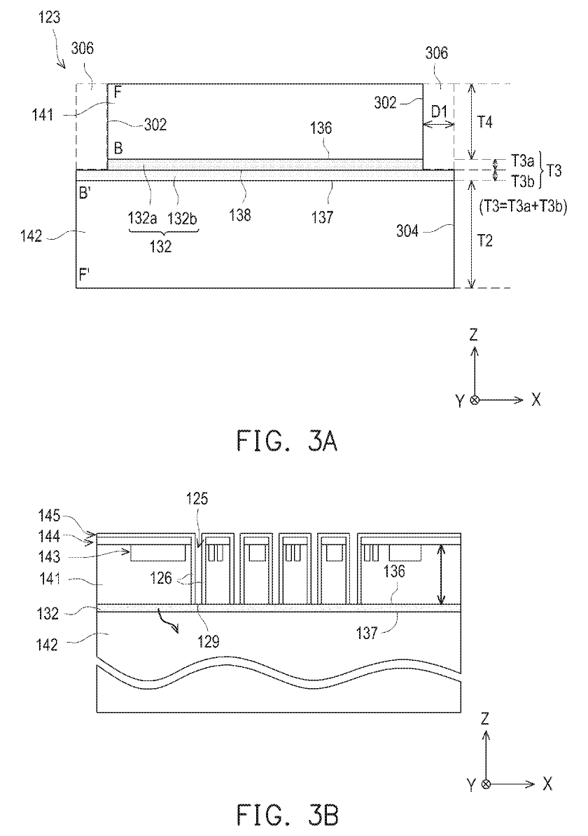

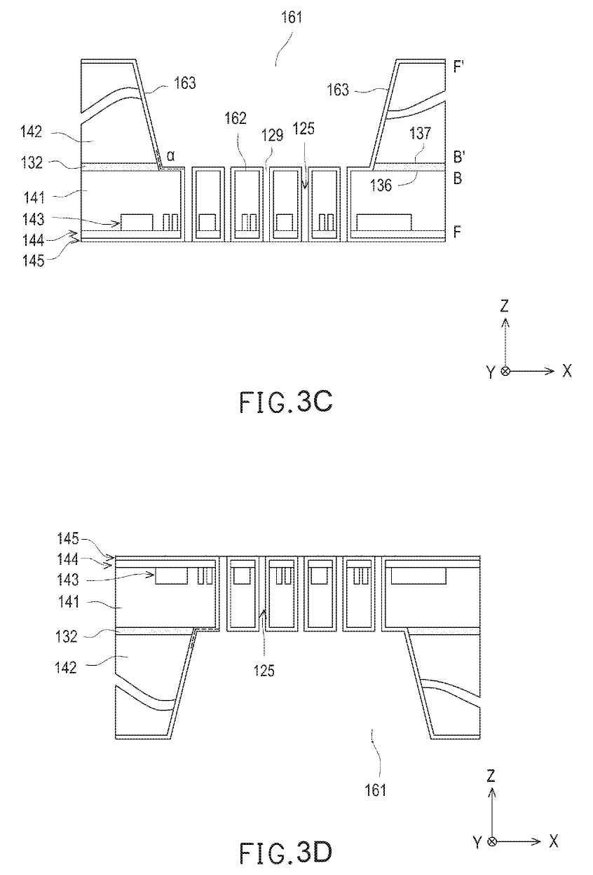

FIG. 2 is a flowchart diagram illustrating an example method 200 for fabrication of a deflecting plate of a direct writing system in accordance with some embodiments. FIGS. 3A-3D are cross-sectional diagrams illustrating the deflecting plate of the direct writing system at various fabrication stages in accordance with some embodiments. It should be understood that FIGS. 3A-3D are not drawn to scale.

In the example shown in FIG. 2, the method 200 includes operations 202, 204, and 206. Additional operations may be performed. Also, it should be understood that the sequence of the various operations discussed above with reference to FIG. 2 is provided for illustrative purposes, and as such, other embodiments may utilize different sequences. These various sequences of operations are to be included within the scope of embodiments.

The method 200 starts with the operation 202. At operation 202, a silicon-on-insulator (SOI) substrate is provided. Example methods of fabricating the SOI substrate will be described in detail below with reference to FIGS. 4-5D. In the example of FIG. 3A, the SOI substrate 123 is provided. The SOI substrate 123 has a device layer 141, a first insulator layer 132a, a second insulator layer 132b, and a handle substrate 142. The first insulator layer 132a is disposed on a back side (B') of the handle substrate 142. The second insulator layer 132b is disposed on a back side (B) of the device layer 141. The first insulator layer 132a and the second insulator layer 132b are bonded at a bonding interface 138 to form the insulator layer 132. In some embodiments, first insulator layer 132a and the second insulator layer 132b are bonded using fusion bonding. The first insulator layer 132a has a thickness ("T3a" as shown in FIG. 3A), measured from a top surface 136 to the bonding interface 138. Likewise, the second insulator layer 132b has a thickness ("T3b" as shown in FIG. 3A), measured from a bottom surface 137 to the bonding interface 138. In some embodiments, T3a is from about 0.1 µm to about 5 µm. In some embodiments, T3b is from about 0.1 µm to about 5 µm. In one embodiment, T3b is close to about 4 µm. Accordingly, the total thickness (T3) of the entire insulator layer 132 is the total of T3a and T3b. In some embodiments, T3 is from about 0.1 µm to about 10 µm. In one embodiment, the total thickness variation (TTV) of the device layer 141 is below 1.5 µm.

Similar to the SOI substrate 123 of FIG. 1B, the device layer 141 has a total thickness ("T4" as shown in FIG. 3A) from about 10 µm to about 100 µm, from about 45 µm to about 55 µm, from about 49 µm to about 51 µm, or close to about 50 µm. The handle substrate 142 has a total thickness (T2) of about 650 µm to about 775 µm, from about 700 µm to about 750 µm, from about 720 µm to about 730 µm, or close to about 725 µm. The SOI substrate 123 may have a total thickness (i.e., T4 + T2 + T3) from about 750 µm to about 850 µm, from about 770 µm to about 800 µm, or close to about 775 µm.

In some embodiments, the device layer 141 has edge regions 306 removed. By removing the edge regions 306, defects are prevented from forming at the edge regions 306 during subsequent grinding or chemical wet etching. The edge defects have a propensity to concentrate at the edge regions 306 and negatively impact the quality of the device layer 141. Removal of the edge regions 306 thus improves the overall quality of the resulting deflecting plate. The edge regions 306 have a trim width (D1), measured by the distance from a side wall 302 of the device layer 141 and a side wall 304 of the handle substrate 142, as illustrated in FIG. 3A. In some embodiments, the trim width (D1) is from about 0.4 millimeters to about 5 millimeters.

At operation 204, multiple deflecting apertures are formed. In the illustrated example of FIG. 3B, multiple deflecting apertures 125 are formed in the device layer 141 of the SOI substrate 123. In some embodiments, at least one additional layer is formed and disposed on the device layer 141 prior to the formation of the deflecting apertures 125. For example, a first additional layer 144, which is a mask layer, can be formed and disposed on the device layer 141. The deflecting apertures 125 may be formed by etching. In one implementation, the device layer 141 is patterned and etched to form the deflecting apertures 125. In one example, the deflecting apertures 125 are formed by etching the area of the device layer 141 that is left exposed by a mask pattern of the first additional layer 144. In one implementation, the mask pattern is a photoresist mask pattern. In another implementation, the mask pattern is a hard mask pattern, and the hard mask pattern may include silicon oxide, silicon nitride, silicon oxynitride, or combinations thereof. In one implementation, the device layer 141 is etched to form the deflecting apertures 125 using wet etching. In another implementation, the device layer 141 is etched to form the deflecting apertures 125 using dry etching. In one example, the device layer 141 is etched to form the deflecting apertures 125 using plasma etching.

The aspect ratio of the deflecting aperture 125 may be controlled by the mask pattern and the parameters of the etching process. As mentioned above, the deflecting aperture 125 may have a relatively high aspect ratio. In some implementations, the aspect ratio is from about 1 to about 100, or from about 5 to about 50. In other implementations, the aspect ratio is larger than 100.

In some embodiments, multiple devices 143 are formed before or after the formation of the deflecting apertures 125. As mentioned above, the devices 143 may be configured to provide a control signal (e.g., a control current) applied to each of the components corresponding to one of the deflecting apertures 125, and the control signal can precisely control the direction and degree of electron deflection for each deflecting aperture 125. In some implementations, a second additional layer 145, which is a protective layer, is formed and disposed on the first additional layer 144. The second additional layer 145 disposed on the first additional layer 144 may be used as a bonding layer for bonding to a hard mask in a subsequent operation. In some implementations, a protective layer is disposed on the circumferential side wall 126 of each deflecting aperture 125.

It is important to note that the insulator layer 132 functions as a "stop layer" to guide the progression of the etching. Due to the barrier property and the relatively high resistance to etching, the insulation layer 132 may effectively stop the etching of the device layer at the top surface 136 when the deflecting apertures 125 are formed. Further etching through the insulator layer 132 is prevented. Because of the insulator layer 132, the bottom open end 129 of each deflecting aperture 125 may be aligned or substantially aligned to each other in the X-Y plane and coplanar with the top surface 136 of the insulator layer 132. Accordingly, the multiple deflecting apertures 125 may have a high degree of uniformity in the vertical dimension.

In the conventional methods, the back side of the device layer is thinned down until a predetermined distance to the bottom open ends of the deflecting apertures is achieved. The thinning process may result in the formation of wafer cracks. A handle substrate is then bonded to the back side of the device layer. The bonding process may result in bonding failure. Additionally, due to the predetermined distance to the bottom open ends of the deflecting apertures, the device layer has to be etched through the predetermined distance in the vertical direction, resulting in poor uniformity in the vertical length of the deflecting apertures because of the isotropic nature of the etching process employed.

As an example of the conventional method, deflecting apertures are formed by etching a device layer in a direction from a front side of the device layer to a back side of the device layer without using an insulator layer to stop the etching. Next, a thinning process is performed to grind the device layer in a direction from the back side to the front side of the device layer. The grinding process is stopped at an appropriate level where a desired thickness of the device layer is obtained. A predetermined distance to the bottom open ends is achieved. Then, a bonding layer is disposed on the back side of the device layer for subsequent bonding to a handle substrate.

However, this conventional method has many drawbacks. First, because the pre-formed deflecting apertures generate voids in the device layer, the grinding process, if not carefully controlled, may cause serious cracks of the device layer. Second, the ground side of the device layer may not be sufficiently flat due to the pre-formed deflecting apertures, which may further cause bonding failure when bonding the handle substrate to the device layer in the subsequent step. In addition, the bonding layer disposed on the ground side of the device layer has the predetermined distance from the bottom open ends of the deflecting apertures, the device layer has to be etched through the predetermined distance in the vertical direction, resulting in poor uniformity in the vertical length of the deflecting apertures because of the isotropic nature of the etching process employed. Therefore, the bottom open ends of the deflecting apertures are not substantially aligned in the X-Y plane, resulting in poor uniformity in the vertical length of the deflecting apertures.

In contrast, the method 200 according to the present disclosure advantageously employs the SOI substrate 123. The SOI substrate 123 is pre-fabricated. Therefore, wafer cracks can be avoided because no thinning process is needed to be applied to the back side of the device layer 141 after the deflecting apertures 125 are fabricated. Additionally, bonding failure can be avoided because the handle substrate 142 has been bonded to the device layer 141 through the insulator layer 132. Lastly, the bottom open ends 129 are substantially coplanar with the top surface 136 of the insulator layer 132, there is no device layer that has to be etched through. Thus, the uniformity in the vertical length of the deflecting apertures is significantly improved. From another perspective, the insulator layer 132 functions as a benchmark to guide the formation of both the deflecting apertures 125 in the device layer 141 and the cavity 161 in the handle substrate 142 during the respective etching processes.

At operation 206, a cavity is formed in the handle substrate. In the illustrated example of FIG. 3C, the cavity 161 is formed in the handle substrate 142 and connected to the deflecting apertures 125. In some implementations, operation 206 further includes multiple sub-operations. For example, the structure resulting from operation 204 is flipped; a first etching process is performed to etch an exposed region of the handle substrate until the insulator layer is exposed; a second etching process is performed to etch the exposed region of the insulator layer.

In the example shown in FIG. 3C, the first etching process is performed downwardly in the direction from the front side (F') to the back side (B') of the handle substrate 142. In some embodiments, the first etching may be performed with a relatively high etching rate. In some implementations, the first etching process is a dry etching process. In one example, the dry etching process is a reactive ion etching (RIE) process. After the first etching process, a portion of the insulator layer 132 is exposed.

During the second etching process, the etching rate may be reduced so that the etching of the insulator layer 132 can be better controlled. The reduced etching rate can prevent the insulator layer 132 from being consumed too fast in an uncontrolled manner and improve the flatness of the cavity bottom wall 162. In some implementations, the second etching process is a dry etching process where an etchant is used to etch and consume an exposed region of the insulator layer 132. In one example, the dry etching process is an RIE process. After the second etching process, the exposed region of the insulator layer 132 is removed.

In some implementations, an additional over-etching step may be employed after the second etching process to make sure the exposed region of the insulator layer 132 is completely removed. As such, the spatial connection between the cavity 161 and the deflecting apertures 125 is assured.

In the example illustrated in FIG. 3D, the structure generated from operation 206 is flipped, in a position that is typically used in the configuration shown in FIG. 1A.

### Example SOI Substrate Used for the Fabrication of the Direct Writing System

Semiconductor-on-insulator (SOI) substrates have emerged as an alternative to bulk semiconductor substrates. An SOI substrate generally comprises a handle substrate, an insulator layer overlying the handle substrate, and a device layer overlying the insulator layer. Among other things, an SOI substrate leads to reduced parasitic capacitance, reduced leakage current, reduced latch-up, and improved semiconductor device performance (e.g., lower power consumption and higher switching speed).

However, the device layer and the insulator layer of a conventional SOI substrate are generally characterized by relatively small thicknesses. For example, the device layer and the insulator layer may be limited to a device layer thickness less than about 0.27 µm and an insulator layer thickness less than about 0.68 µm, respectively.

The small thicknesses limit the use of the SOI substrate. For example, the small thickness of the device layer may limit devices on the device layer to small semiconductor junctions (e.g., small PN junctions). As another example, the small thickness of the insulator layer may limit electrical isolation between devices on the device layer.

To address these limitations, a method for fabricating an SOI substrate with a relatively large device layer thickness is provided. As will be described below with reference to FIGS. 4-5D, the method includes, among other operations, bonding a handle substrate and a sacrificial substrate together, followed by two thinning processes on both sides. The resultant SOI substrate has a total thickness ranging from 750 µm to 850 µm. The thickness of the device layer is between 10 µm and 100 µm.

FIG. 4 is a flowchart diagram illustrating an example method 400 for fabricating an example SOI substrate in accordance with some embodiments. FIGS. 5A-5D are cross-sectional diagrams illustrating various stages during the fabrication of the example SOI substrate.

In the example shown in FIG. 4, the method 400 includes operations 402, 404, 406, 408, 410, 412, 414, and 416. Additional operations may be performed. Also, it should be understood that the sequence of the various operations discussed above with reference to FIG. 4 is provided for illustrative purposes, and as such, other embodiments may utilize different sequences. These various sequences of operations are to be included within the scope of embodiments.

At operation 402, a first insulator layer is formed on a handle substrate. In some embodiments, the handle substrate comprises silicon. In other embodiments, the handle substrate may comprise one or more other semiconductor materials. In some embodiments, the first insulator layer is formed on an upper surface of the handle substrate. In other embodiments, the first insulator layer completely encloses the handle substrate. In some embodiments, the first insulator layer comprises silicon oxide. In other embodiments, the first insulator layer comprises other dielectric materials.

In some implementations, the first insulator layer is formed using thermal oxidation, chemical vapor deposition (CVD), physical vapor deposition (PVD), some other deposition process, or any combination thereof. For example, the first insulator layer may be deposited by a dry oxidation process using oxygen gas or some other gas as an oxidant. As another example, the first insulator layer may be deposited by a wet oxidation process using water vapor as an oxidant. It should be understood that other suitable processes can be used in other embodiments.

In the example shown in FIG. 5A, the first insulator layer 506a completely encloses the handle substrate 504. The thickness of the first insulator layer 506a is denoted by Toxa. In one example, the thickness of the first insulator layer 506a is between 0.1 µm and 5 µm.

At operation 404, a device layer is formed on a sacrificial substrate. In some embodiments, the device layer comprises silicon. In other embodiments, the device layer may comprise one or more other semiconductor materials. In some embodiments, the device layer is or comprises the same semiconductor material as the sacrificial substrate with the same doping type as the sacrificial substrate and a lower doping concentration than the sacrificial substrate. For example, the sacrificial substrate may be or comprise P+ monocrystalline silicon, whereas the device layer may be or comprise P− monocrystalline silicon.

In some implementations, the device layer is formed using molecular beam epitaxy (MBE), vapor phase epitaxy (VPE), liquid phase epitaxy (LPE), other epitaxial processes, or any combination thereof.

Because the device layer can be formed by, for example, an epitaxy process and subsequently transferred to the handle substrate, the device layer may be formed with a relatively large thickness (e.g., a thickness greater than about 0.3 µm) as compared to a conventional fabrication method of an SOI substrate. Epitaxy is not subject to the thickness restrictions associated with other approaches for forming the device layer.

At operation 406, edge regions of the sacrificial substrate and the device layer are removed. By removing the edge regions, defects are prevented from forming at the edge regions during subsequent thinning processes (e.g., grinding, CMP, and the like). The edge defects have a propensity to concentrate at the edge regions and negatively impact the quality of the device layer. In some implementations, the edge regions of the sacrificial substrate and the device layer are removed using a photolithography process followed by an etching process.

At operation 408, a second insulator layer is formed on the device layer. In some embodiments, the second insulator layer is formed on an upper surface of the device layer (before the device layer and the sacrificial substrate is flipped subsequently). In other embodiments, the second insulator layer completely encloses the device layer and the sacrificial substrate. In some embodiments, the second insulator layer comprises silicon oxide. In other embodiments, the second insulator layer comprises other dielectric materials. In some embodiments, the second insulator layer comprises the same dielectric material (e.g., silicon oxide) as that of the first insulator layer.

In some implementations, the second insulator layer is formed using thermal oxidation, chemical vapor deposition (CVD), physical vapor deposition (PVD), some other deposition process, or any combination thereof. For example, the second insulator layer may be deposited by a dry oxidation process using oxygen gas or some other gas as an oxidant. As another example, the second insulator layer may be deposited by a wet oxidation process using water vapor as an oxidant. It should be understood that other suitable processes can be used in other embodiments.

In the example shown in FIG. 5B, the device layer 508 is formed on the sacrificial substrate 552, and the second insulator layer 506b completely encloses the sacrificial substrate 552 and the device layer 508. The thickness of the second insulator layer 506b is denoted by Toxb. In one example, the thickness of the second insulator layer 506b is 4 µm. As shown in FIG. 5B, the edge regions of the device layer 508 and the sacrificial substrate 552 have been removed.

At operation 410, the sacrificial substrate is bonded to the handle substrate. The first insulator layer and the second insulator layer are bonded together so that the device layer, the first insulator layer, and the second insulator layer are between the handle substrate and the sacrificial substrate. In some implementations, the sacrificial substrate is bonded to the handle substrate using fusion bonding. The fusion bonding may, for example, be performed with pressure at about 1 standard atmosphere (atm), about 0.5-1.0 atm, about 1.0-1.5, or about 0.5-1.5 atm. In other implementations, the sacrificial substrate is bonded to the handle substrate using vacuum bonding or other suitable bonding processes. In some embodiments, an anneal process may be performed after the bonding process.

In the example shown in FIG. 5C, the first insulator layer 506a and the second insulator layer 506b are bonded together at a bonding interface 592 so that the device layer 508, the first insulator layer 506a, and the second insulator layer 506b are between the handle substrate 504 and the sacrificial substrate 552.

At operation 412, the sacrificial substrate is removed. In some implementations, the sacrificial substrate is removed by an etching process. The etching process removes the sacrificial substrate and stops on the device layer due to the selectivity of the etchant used during the etching process. It should be understood that the sacrificial substrate may be removed by other suitable processes in other implementations.

At operation 414, a first thinning process is performed on the device layer at the front side of the SOI substrate. In some implementations, the first thinning process is a mechanical grinding process. In some implementations, the first thinning process is a CMP process. In other implementations, the first thinning process is a mechanical grinding process followed by a CMP process. In one example, the thickness of the device layer is 59 µm after the mechanical grinding process and 50 µm after the CMP process. In one embodiment, the total thickness variation (TTV) of the device layer is below 1.5 µm.

At operation 416, a second thinning process is performed on the handle substrate at the back side of the SOI substrate. The SOI substrate is flipped, and the second thinning process is performed on the handle substrate. In the embodiment where the first insulator layer completely encloses the handle substrate, the first insulator layer at the back side of the SOI substrate is removed before the handle substrate is thinned. In some implementations, the second thinning process is a mechanical grinding process. In some implementations, the second thinning process is a CMP process. In other implementations, the second thinning process is a mechanical grinding process followed by a CMP process. In one example, the thickness of the handle substrate is between 650 µm and 775 µm after the second thinning process.

In the example shown in FIG. 5D, an SOI substrate is fabricated after operations 412, 414, and 416. The device layer 508 is exposed and has a desired thickness after the first thinning process. The handle substrate 504 has a desired thickness after the second thinning process. The first insulator layer 506a and the second insulator layer 506b are bonded at the bonding interface 592.

The relatively large thickness of the device layer 508 may, for example, enable the formation of large semiconductor junctions (e.g., PN junctions) upon which certain devices may depend. The relatively large thickness of the first insulator layer 506a and the relatively large thickness of the second insulator layer 506b may, for example, facilitate enhanced electrical isolation between devices fabricated on the device layer 508 and reduce the leakage current of these devices. Applications that may benefit from the relatively large thicknesses include, for example, high voltage (e.g., greater than about 100 volts) applications, bipolar complementary metal-oxide-semiconductor (CMOS) double-diffused metal-oxide-semiconductor (DMOS) (BCD) applications, embedded flash (eFlash) applications, CMOS image sensor (CIS) applications, near-infrared (NIR) applications, and other applications.

It should be understood that the SOI substrate shown in FIG. 5D and the corresponding method 400 shown in FIG. 4 are exemplary rather than limiting. One of ordinary skill in the art would recognize many variations, modifications, and alternatives. For example, in some embodiments, the second thinning process may be omitted when the thickness of the handle substrate 504 is the desired thickness and the handle substrate 504 is completely enclosed by the first insulator layer 506a. As another example, the geometries (e.g., the trim width) of the SOI substrate may vary in other embodiments as needed.

### Summary

In accordance with some aspects of the disclosure, a deflecting plate used for electron beam lithography (EBL) is provided. The deflecting plate includes a silicon-on-insulator (SOI) substrate. The SOI substrate includes: an insulator layer having a top surface and a bottom surface; a device layer coupled to the insulator layer at the top surface, wherein a plurality of deflecting apertures are disposed in the device layer, each of the plurality of deflecting apertures extending from a top open end to a bottom open end in a vertical direction through the device layer, and wherein the bottom open end is coplanar with the top surface of the insulator layer; and a handle substrate coupled to the insulator layer at the bottom surface, wherein a cavity is disposed in the handle substrate, the cavity extending from a cavity open end to a cavity bottom wall, and wherein the cavity bottom wall is coplanar with the top surface of the insulator layer, such that the bottom open end of each of the plurality of deflecting apertures is exposed to and in spatial connection with the cavity.

In accordance with some aspects of the disclosure, a method of fabricating a deflecting plate used for electron beam lithography (EBL). The method includes the following operations: providing a silicon-on-insulator (SOI) substrate, the SOI substrate including an insulator layer having a top surface and a bottom surface; a device layer coupled to the insulator layer at the top surface; and a handle substrate coupled to the insulator layer at the bottom surface; forming a plurality of deflecting apertures in the device layer, wherein each of the plurality of deflecting apertures extends from a top open end to a bottom open end in a vertical direction through the device layer, and wherein the bottom open end is coplanar with the top surface of the insulator layer; and forming a cavity in the handle substrate, wherein the cavity extends from a cavity open end to a cavity bottom wall, and wherein the cavity bottom wall is coplanar with the top surface of the insulator layer, such that the bottom open end of each of the plurality of deflecting apertures is exposed to and in spatial connection with the cavity.

In accordance with some aspects of the disclosure, a deflecting plate used for electron beam lithography (EBL) is provided. The deflecting plate includes: a silicon-on-insulator (SOI) substrate. The SOI substrate includes: a handle substrate; an insulator layer coupled to the handle substrate at a first surface of the insulator layer; and a device layer coupled to the insulator layer at a second surface of the insulator layer. The deflecting plate further includes: a plurality of deflecting apertures disposed in the device layer, wherein each of the plurality of deflecting apertures extends from a top open end to a bottom open end in a vertical direction through the device layer, wherein the bottom open end is coplanar with the second surface of the insulator layer, and wherein a plurality of electron beams pass through the plurality of deflecting apertures during an EBL process; and a cavity disposed in the handle substrate, the cavity having a cavity open end, a cavity bottom wall, and a circumferential cavity side wall, wherein the cavity bottom wall is coplanar with the second surface of the insulator layer, such that the bottom open end of each of the plurality of deflecting apertures is exposed to and in spatial connection with the cavity.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of fabricating a deflecting plate used for electron beam lithography (EBL), the method comprising:
providing a silicon-on-insulator (SOI) substrate, the SOI substrate comprising:
an insulator layer having a top surface and a bottom surface;
a device layer coupled to the insulator layer at the top surface; and
a handle substrate coupled to the insulator layer at the bottom surface;
forming a plurality of deflecting apertures in the device layer, wherein each of the plurality of deflecting apertures extends from a top open end to a bottom open end in a vertical direction through the device layer, and wherein the bottom open end is coplanar with the top surface of the insulator layer; and
forming a cavity in the handle substrate, wherein the cavity extends from a cavity open end to a cavity bottom wall, and wherein the cavity bottom wall is coplanar with the top surface of the insulator layer, such that the bottom open end of each of the plurality of deflecting apertures is exposed to and in spatial connection with cavity.

2. The method of claim 1, further comprising:
forming a plurality of devices in the device layer, wherein each of the plurality of devices corresponds to one of the plurality of deflecting apertures and configured to control electron deflection for the corresponding deflecting aperture.

3. The method of claim 1, wherein forming the plurality of deflecting apertures further comprises:
patterning and etching the device layer to form the plurality of deflecting apertures.

4. The method of claim 1, wherein forming the cavity further comprises:
performing a first etching process to remove an exposed region of the handle substrate to expose a region of the insulator layer; and
performing a second etching process to remove the exposed region of the insulator layer.

5. The method of claim 4, wherein forming the cavity further comprises:
performing an over-etching process.

6. The method of claim 1, further comprising:
disposing a mask layer on a front side of the device layer prior to forming the plurality of deflecting apertures.

7. The method of claim 1, further comprising:
removing edge regions of the device layer to prevent defect formation.

8. The method of claim 1, wherein the insulator layer functions as a stop layer to stop an etching of the device layer at the top surface of the insulator layer during the forming of the plurality of deflecting apertures.

9. The method of claim 3, wherein the insulator layer comprises a first insulator layer disposed on the handle substrate and a second insulator layer disposed on a sacrificial substrate, and wherein bonding the sacrificial substrate to the handle substrate comprises bonding the first insulator layer to the second insulator layer using fusion bonding.

10. The method of claim 1, wherein the plurality of deflecting apertures are formed to have an aspect ratio between 5 and 50.

11. A method of fabricating a deflecting plate used for electron beam lithography (EBL), the method comprising:
providing a silicon-on-insulator (SOI) substrate comprising an insulator layer, a device layer coupled to a top surface of the insulator layer, and a handle substrate coupled to a bottom surface of the insulator layer;
etching the device layer to form a plurality of deflecting apertures, wherein the insulator layer functions as a stop layer such that a bottom open end of each of the plurality of deflecting apertures is coplanar with the top surface of the insulator layer; and
etching the handle substrate to form a cavity having a cavity bottom wall that is coplanar with the top surface of the insulator layer, such that the bottom open end of each of the plurality of deflecting apertures is exposed to the cavity.

12. The method of claim 11, wherein etching the handle substrate to form the cavity comprises:
performing a first etching process to etch an exposed region of the handle substrate until the insulator layer is exposed.

13. The method of claim 12, wherein the first etching process is a dry reactive ion etching (RIE) process.

14. The method of claim 12, wherein etching the handle substrate to form the cavity further comprises:
performing a second etching process to etch an exposed region of the insulator layer, wherein the second etching process has a reduced etching rate compared to the first etching process to control consumption of the insulator layer and flatten the cavity bottom wall.

15. The method of claim 11, further comprising:
disposing a protective layer on a circumferential side wall of each of the plurality of deflecting apertures.

16. The method of claim 11, wherein the cavity is formed to have a circumferential cavity side wall that forms an angle greater than 85 degrees with the insulator layer.

17. A method of fabricating a deflecting plate used for electron beam lithography (EBL), the method comprising:
providing a silicon-on-insulator (SOI) substrate comprising a handle substrate, an insulator layer, and a device layer;
forming a plurality of deflecting apertures extending vertically through the device layer to a top surface of the insulator layer;
performing a first etching process in a direction from a back side of the handle substrate to expose a region of the insulator layer; and
performing a second etching process to remove the exposed region of the insulator layer to form a cavity bottom wall that is coplanar with the top surface of the insulator layer.

18. The method of claim 17, further comprising:
performing an over-etching step after the second etching process to ensure the exposed region of the insulator layer is completely removed.

19. The method of claim 17, wherein the device layer has a total thickness from 45 μm to 55 μm, and the handle substrate has a total thickness from 700 μm to 750 μm.

20. The method of claim 17, wherein the plurality of deflecting apertures are formed without applying a thinning process to a back side of the device layer after the plurality of deflecting apertures are fabricated.
